(19) United States
(12) Patent Application Publication
(10) Pub. No.: US 2019/0013229 A1
(43) Pub. Date: Jan. 10, 2019

(54) ALIGNER STRUCTURE AND ALIGNMENT METHOD

(71) Applicant: VNI SOLUTION CO., LTD, Daejeon (KR)

(72) Inventors: Saeng Hyun CHO, Gyeonggi-do (KR); Sung Il AHN, Gyeonggi-Do (KR)

(21) Appl. No.: 15/562,362

(22) PCT Filed: Apr. 1, 2016
(86) PCT No.: PCT/KR2016/003379

§ 371 Date: Sep. 24, 2018

(30) Foreign Application Priority Data
Apr. 1, 2015 (KR) 10-2015-0046440

(51) Int. Cl. H01L 21/68; H01L 21/687; H01L 21/683; C23C 14/02

(52) U.S. Cl. CPC H01L 21/682; H01L 21/68728; H01L 51/56; H01L 21/68764; C23C 14/024; H01L 21/6831

(57) ABSTRACT

The present disclosure is directed to an aligner structure and an alignment method for processing a substrate when a substrate and a mask are vertically arranged by providing an alignment structure for fixing and aligning the substrate and the mask with each other while the substrate and the mask are vertically arranged. The aligner structure comprises a mask clamping portion which is installed in the process chamber to clamp the mask; a substrate clamping portion which clamps a substrate carrier on which the substrate is held by an electrostatic chuck; an alignment portion which relatively moves the substrate carrier with respect to the mask such that the substrate and the mask are aligned with each other; and an adhesion driving portion which causes the substrate and the mask, which are aligned by the alignment portion, to adhere to each other.

### TECHNICAL FIELD

The present invention relates to a vapor deposition device and, more specifically, to an aligner structure and an alignment method which align a substrate with a mask in order to perform a deposition process on the substrate.

### BACKGROUND ART

A vapor deposition device refers to a device for forming a thin film on a substrate such as a surface of a wafer for manufacturing a semiconductor device, a substrate for manufacturing a liquid crystal display (LCD), a substrate for manufacturing an organic light emitting diode (OLED), etc. by using a chemical vapor deposition (CVD), a physical vapor deposition (PVD), an evaporation deposition, etc.

As for the substrate for manufacturing an OLED, a process for forming a thin film on a substrate surface by evaporating an organic material, an inorganic material, a metal, etc. while depositing a deposition material is widely used.

The vapor deposition device, which forms a thin film by evaporating a deposition material, includes a deposition chamber in which a substrate for deposition is loaded, and a source which is installed inside the deposition chamber and heats up and evaporates the deposition material such that the deposition material is evaporated on the substrate, and the vapor deposition device performs a substance processing by forming the thin film on the substrate surface using the evaporated deposition material.

Also, the source used for an OLED vapor deposition device is installed inside the deposition chamber and has a structure which heats up and evaporates the deposition material such that the deposition material is evaporated on the substrate. Various structures such as those disclosed in Korea patent publication No. 10-2009-0015324 and Korea patent publication No. 10-2004-0110718, etc. can be envisaged depending on an evaporation method.

The OLED vapor deposition device is formed by coupling a substrate S with an anode, a cathode, an organic film, etc. with predetermined patterns with a mask M, as can be seen in FIG. 1.

Here, an alignment process of the substrate S and the mask M should be performed before the deposition process. In the prior art, the substrate S and the mask M are aligned with each other outside the process chamber 10 and then transferred into the process chamber 10 such that the deposition process can be performed.

However, when the substrate S and the mask M, which are aligned outside the process chamber 10 according to the prior art, are transferred into the process chamber 10, the alignment state of the substrate S and the mask M can be interrupted due to vibrations, etc., which can result in deposition failures.

More particularly, when the substrate is transferred and the deposition process is performed while the substrate S is in a vertical state, a small relative movement can occur between the substrate S and the mask M since there is no alignment structure proposed inside the process chamber 10, and this relative movement can cause failures in the deposition process and degrade the deposition process.

### DETAILED DESCRIPTION OF THE INVENTION

### Technical Problem

In order to solve the problems discussed above, the purpose of the present invention is to provide: an aligner structure which is capable of processing a good substrate when a substrate S and a mask M are vertically arranged, by providing an alignment structure for fixing and aligning the substrate S and the mask M with each other while the substrate S and the mask M are vertically arranged; and an alignment method.

### Technical Solution

In order to solve the technical problem discussed above, the aligner structure of substrate processing apparatus for processing a substrate S after the substrate S and a mask M are transferred vertically to a process chamber 10, respectively, and the substrate S and the mask M are transferred and adhered to each other according to the present invention is characterized in comprising: a mask clamping portion 100 which is installed in the process chamber 10 to clamp the mask M; a substrate clamping portion 200 which clamps a substrate carrier 320 on which the substrate S is absorbed and fixed by an electrostatic chuck; an alignment portion 400 which relatively moves the substrate carrier 320 with respect to the mask M such that the substrate S, which is clamped by the substrate clamping portion 200, and the mask M, which is clamped by the mask clamping portion 100 are aligned with each other; and an adhesion driving portion which causes the substrate S and the mask M, which are aligned by the alignment portion 400, to adhere to each other.

According to an embodiment, the mask clamping portion 100 can clamp the mask M by way of a magnetic force coupling, a screw coupling, or a fitting coupling.

And the substrate clamping portion 200 can clamp the substrate carrier 320 by way of a magnetic force coupling, a screw coupling, or a fitting coupling.

According to an embodiment, the mask clamping portion 100 can include a fitting portion 110, which is fitted into and coupled with a protruding portion 310, and a coupling maintaining portion 120 which maintains a coupling state between the protruding portion 310 and the fitting portion 110 while the fitting portion 110 is fitted into and coupled with the protruding portion 310, wherein the protruding portion 310 protrudes from a bottom surface of the mask M.

And the substrate clamping portion 200 can include a fitting portion 210, which is fitted into and coupled with a protruding portion 321, and a coupling maintaining portion 220 which maintains a coupling state between the protruding portion 321 and the fitting portion 210 while the fitting portion 210 is fitted into and coupled with the protruding portion 321, wherein the protruding portion 321 protrudes from a bottom surface of the substrate carrier 320.

According to an embodiment, the fitting portion 110 and 210 is provided with the insertion portion 111 and 211 into which the protruding portion 310 and 321 is inserted, and the coupling maintaining portion 120 and 220 can include ball members 121 and 221, which are inserted into at least two groove portions 311 and 322, and pressurizing members 122 and 222 which pressurize the ball members 121 and 221 against the groove portions 311 and 322, wherein the groove portions 311 and 322 are formed on an outer circumferential surface of the protruding portion 310 and 321 along the outer circumferential surface.

And the pressurizing members 122 and 222 are provided with inclined surfaces 123 and 223, which come into contact with the ball members 121 and 221 and can move along a longitudinal direction of the protruding portion 310 and 321 to pressurize the ball members 121 and 221 against the groove portions 311 and 322.

The adhesion driving portion can include a linear driving unit which is installed on at least one of the substrate clamping portion 200 and the mask clamping portion 100 to cause the mask M and the substrate S to adhere to each other.

The alignment portion 300 can include a first linear moving portion, a second linear moving portion, and a third linear moving portion which linearly move one of the mask M and the substrate S in a direction parallel with the substrate S.

Linear moving directions of the first linear moving portion, the second linear moving portion, and the third linear moving portion can be perpendicular to one another and inclined with respect to a vertical direction.

The substrate processing apparatus can perform a deposition process by using an evaporation source which evaporates a deposition material, and the deposition material contains at least one of an organic material, an inorganic material, and a metal material.

### Advantageous Effects

According to the present invention, an alignment structure for fixing and aligning the substrate S and the mask M with each other while the substrate S and the mask M are vertically arranged is provided; therefore, the substrate can be processed well in a state where the substrate S and the mask M are vertically arranged.

In addition, according to the present invention, a linear moving direction of one of the substrate S and the mask M while the substrate S and the mask M are vertically arranged is inclined with respect to a vertical direction; therefore, an alignment error due to a mechanical backlash of a linear moving device in the alignment portion can be prevented.

### DESCRIPTION OF THE DRAWINGS

FIG. 1 is a cross-sectional view illustrating an example of a conventional OLED vapor deposition device;

FIGS. 2A-2C are cross-sectional views illustrating an example of a substrate processing apparatus adopting the aligner structure as well as alignment processes according to an embodiment of the present invention;

FIGS. 3A-3B are cross-sectional views illustrating operation processes of a mask clamping;

FIGS. 4A-4B are cross-sectional views illustrating operation processes of a substrate clamping;

FIG. 5 is a side view showing the alignment portion in the aligner structure in FIGS. 2A-2C; and

FIG. 6 is a plan view showing an alignment process between the substrate and the substrate carrier.

### BEST MODE

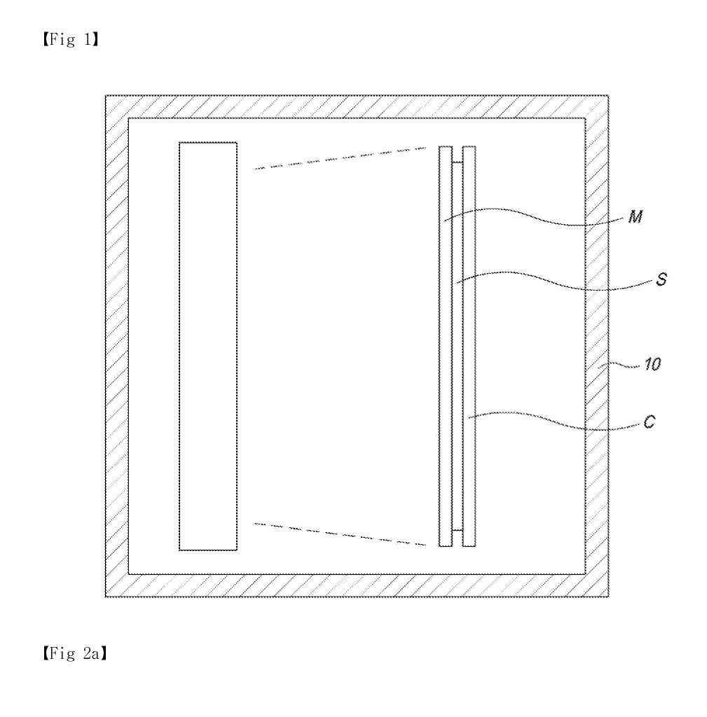

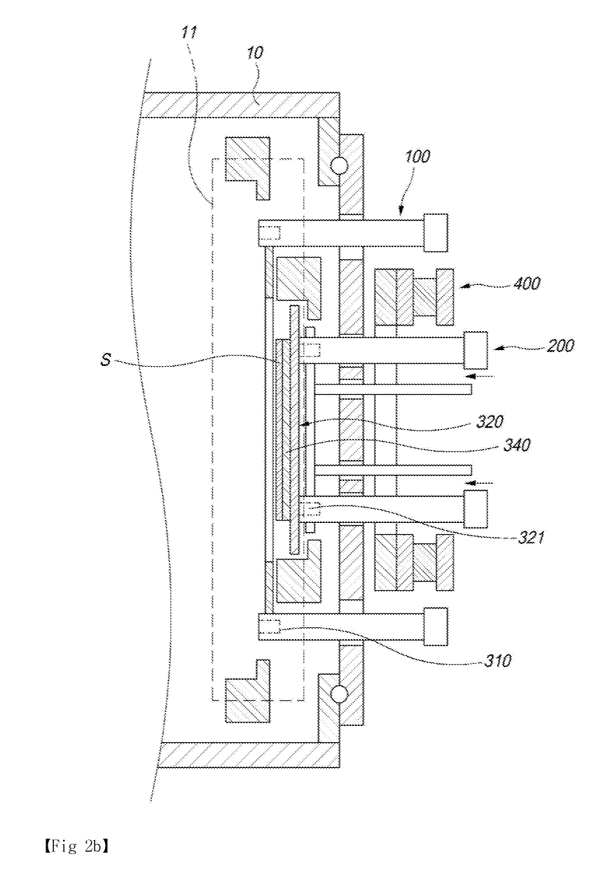

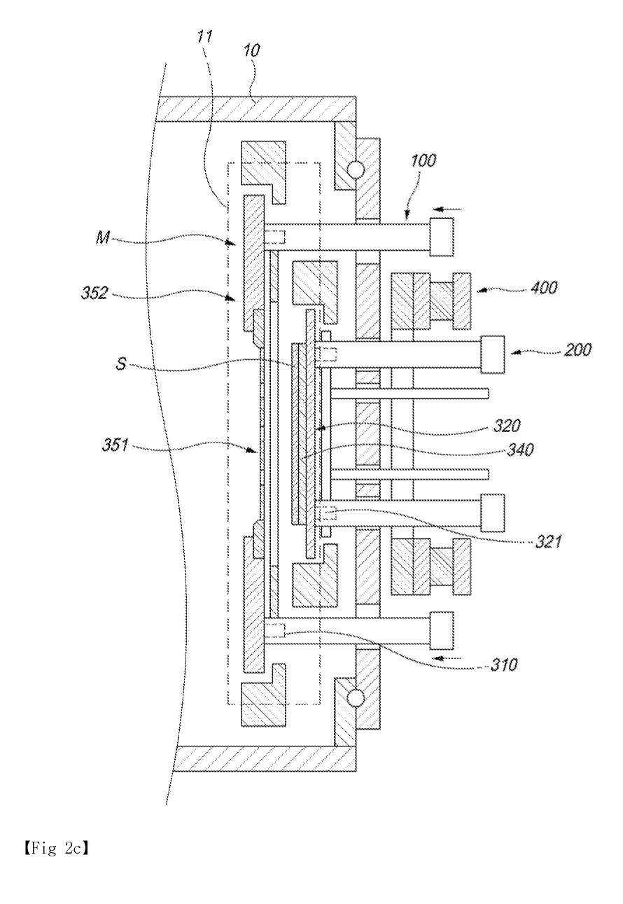

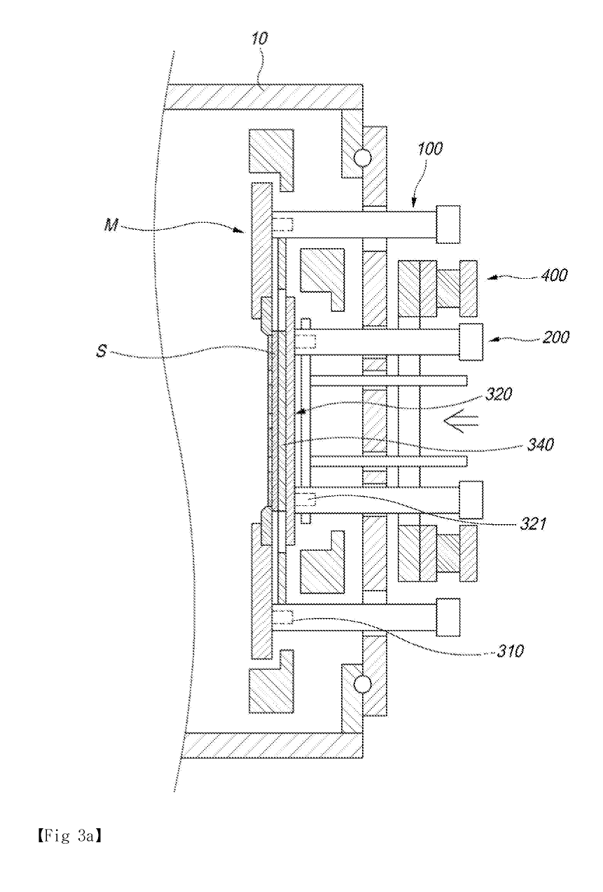

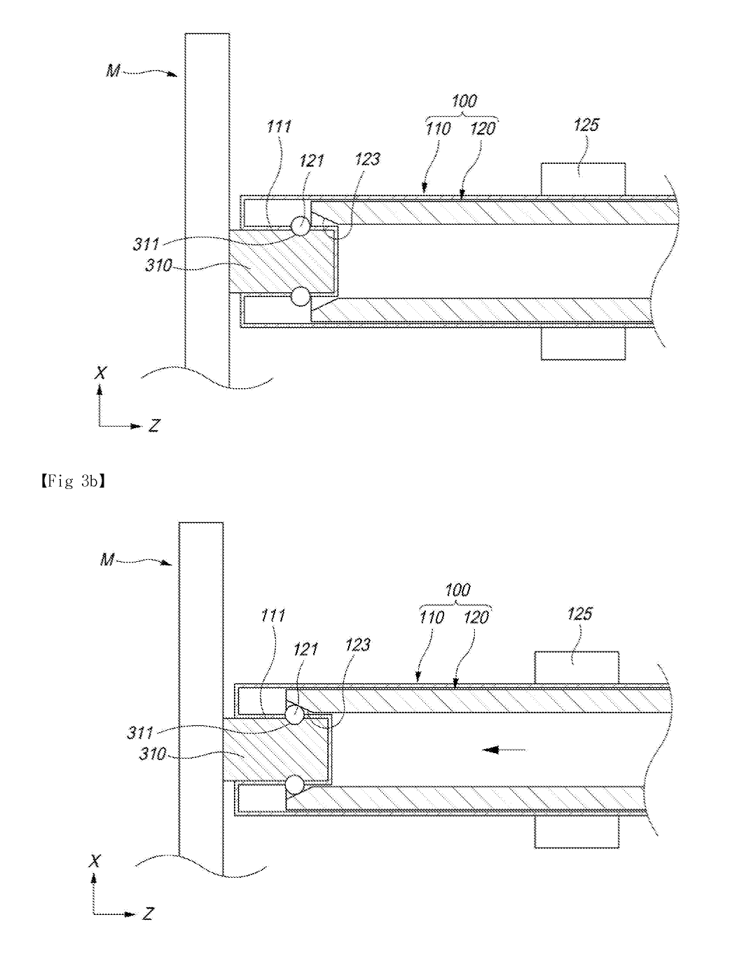

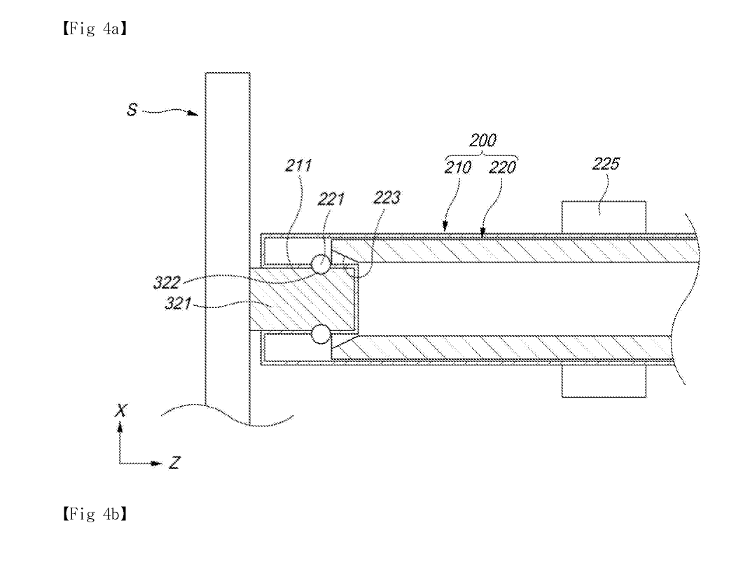

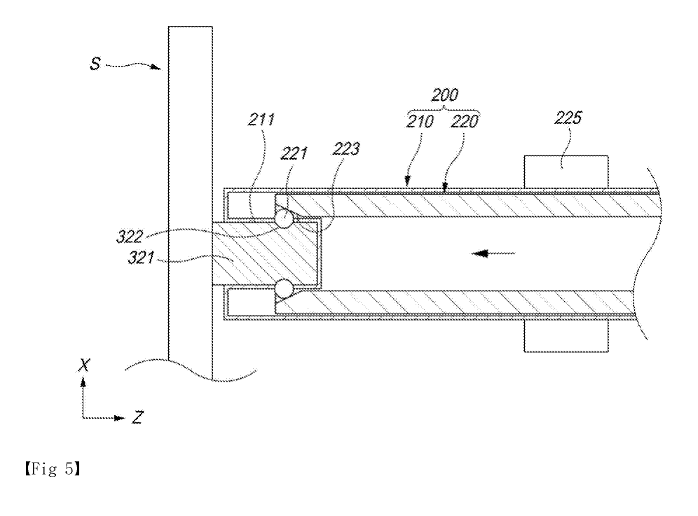

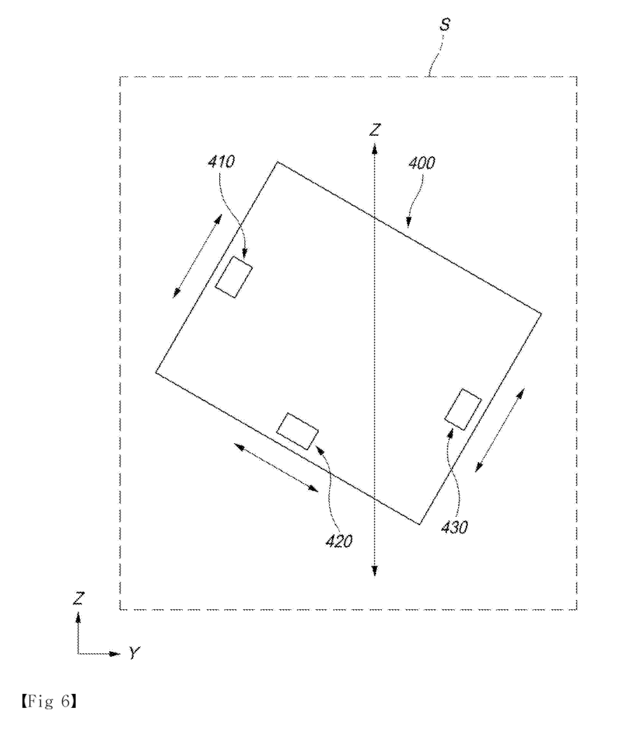

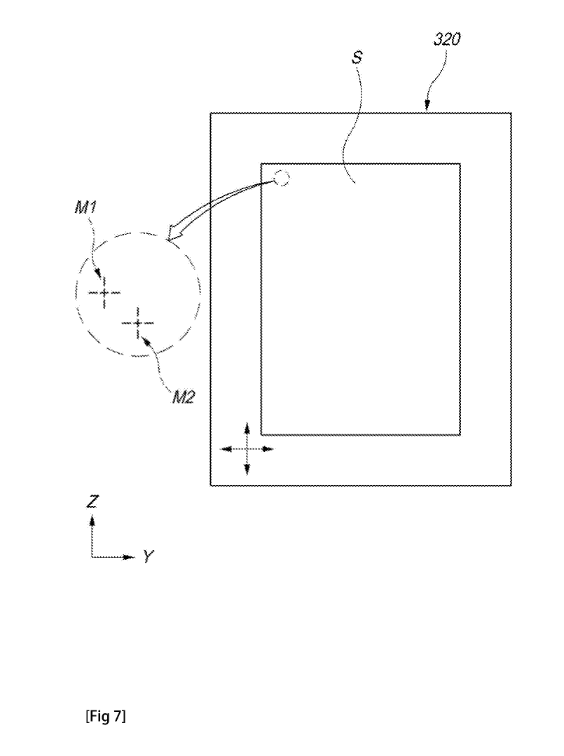

Hereinafter, one embodiment of the present invention will be described in detail by referring to appended drawings. FIGS. 2A-2C are cross-sectional views illustrating an example of a substrate processing apparatus adopting the aligner structure as well as alignment processes according to an embodiment of the present invention; FIGS. 3A-3B are cross-sectional views illustrating operation processes of a mask clamping; FIGS. 4A-4B are cross-sectional views illustrating operation processes of a substrate clamping; and FIG. 5 is a side view showing the alignment portion in the aligner structure in FIGS. 2A-2C.

According to an embodiment of the present invention, the aligner structure of substrate processing apparatus for processing a substrate S after the substrate S and a mask M are transferred vertically to a process chamber 10, respectively, and the substrate S and the mask M are transferred and adhered to each other, comprises: a mask clamping portion 100 which is installed in the process chamber 10 to clamp the mask M; a substrate clamping portion 200 which clamps a substrate carrier 320 on which the substrate S is absorbed and fixed by an electrostatic chuck; an alignment portion 400 which relatively moves the substrate carrier 320 with respect to the mask M such that the substrate S, which is clamped by the substrate clamping portion 200, and the mask M, which is clamped by the mask clamping portion 100 are aligned with each other; and an adhesion driving portion which causes the substrate S and the mask M, which are aligned by the alignment portion 400, to adhere to each other.

The substrate processing apparatus to which the aligner structure according to the present invention is applied is an apparatus in which the substrate S and the mask M are vertically transferred into the process chamber 10, respectively, and the substrate is processed after the substrate S and the mask M are transferred and adhered to each other, and the substrate processing apparatus can be applied to all apparatuses requiring the use of the mask M and the alignment between the substrate S and the mask M during the substrate processing process such as a vapor deposition device using evaporation of a deposition material, a vapor deposition device performing an atomic layer deposition process, etc.

When the substrate S is transferred in a vertical position, the substrate S is preferably transferred while fixed on the substrate carrier 320.

The substrate carrier 320 is a component on which moves with the substrate S fixed thereon, and it can have various structures depending on a fixing type of the substrate S.

According to an embodiment, the substrate carrier 320 can include a support member to which the substrate S is adhered, and an electrostatic chuck 340 which adheres the substrate S against the support member.

The electrostatic chuck 340 is a component which absorbs and fixes the substrate S by using an electromagnetic force when the substrate carrier 320 transfers the substrate S, and it is also a component which receives power from a DC power supply (not shown in the figures) installed in the substrate carrier 320 or from an external DC power supply to generate the electromagnetic force.

The substrate carrier 320 can adopt any transfer type which can transfer the substrate carrier 320 into and out of the process chamber 10 including a roller, magnetic levitation, etc.

In order to accomplish this, a component for transferring the substrate carrier 320 according to the transfer type of the substrate carrier 320 is installed in the process chamber 10.

The mask M can also be transferred into the process chamber 10 in a vertical state by various manners.

According to an embodiment, the mask M can be transferred in any transfer type which can transfer the mask M into and out of the process chamber 10 including a roller, magnetic levitation, etc.

In order to accomplish this, a component for transferring the mask M according to the transfer type of the mask M is installed in the process chamber 10.

The mask M is a component which is adhered to the substrate S such that a substrate processing process such as a patterned deposition, etc. can be performed on the substrate.

According to an embodiment, the mask M can include a mask sheet 351 with patterned openings formed thereon, and a frame member 352 to which the mask sheet 351 is fixed.

The process chamber 10 is a component for providing a processing environment for performing an evaporation deposition process, and it can adopt any possible configuration.

The process chamber 10 contains a predetermined internal space and can be formed as a vessel on which a gate 11 for the substrate S is formed.

And, a ventilating means for maintaining a predetermined pressure for the internal space can be provided in the vessel.

A source 30 is a component which heats up the deposition material to evaporate the deposition material against the substrate S and it can adopt any possible configuration. At least one source 30 can be installed inside the process chamber 10.

The source 30 is a component which evaporates the deposition material including at least one of an organic material, an inorganic material, and a metal material, and can have various embodiments: that is, a crucible for receiving the deposition material and a heater for heating the crucible can be used as the source 30.

In addition to the source 30, various components, which correspond to the substrate processing process being performed, can be installed in the process chamber 10. For example, when the substrate processing process is an atomic layer deposition process, a gas spraying structure for a source gas, a reaction gas, etc. can be installed in the process chamber 10.

The substrate processing apparatus with the configuration mentioned above transfers the substrate S and the mask M into the process chamber 10, respectively, fixes the transferred substrate S and the mask M within the process chamber 10, performs an alignment by using a relative movement of the fixed substrate S and the mask M, adheres the aligned substrate S and the mask M to each other, and then performs the substrate processing process.

In order to perform the substrate processing process, the process chamber 10 includes an aligner structure for performing fixing, aligning, and adhering of the substrate S and the mask M.

In the meantime, the alignment process between the substrate S and the mask M can be performed by various moving methods such as, by moving the mask M while the substrate S is fixed, by moving the substrate S while the mask M is fixed, or by moving both the substrate S and the mask M, to perform the alignment.

### SUMMARY OF THE INVENTION

In the following, an aligner structure according to an embodiment of the present invention will be described.

The aligner structure according to an embodiment of the present invention comprises: a mask clamping portion 100 which is installed in the process chamber 10 to clamp the mask M; a substrate clamping portion 200 which clamps a substrate carrier 320 on which the substrate S is absorbed and fixed by an electrostatic chuck; an alignment portion 400 which relatively moves the substrate carrier 320 with respect to the mask M such that the substrate S, which is clamped by the substrate clamping portion 200, and the mask M, which is clamped by the mask clamping portion 100 are aligned with each other; and an adhesion driving portion which causes the substrate S and the mask M, which are aligned by the alignment portion 400, to adhere to each other.

The mask clamping portion 100 is characterized in being installed in the process chamber 10 to clamp the mask M and can have various configuration depending on the clamping type of the mask M.

According to an embodiment, the mask clamping portion 100 can be configured to clamp the mask M by way of a magnetic force coupling, a screw coupling, or a fitting coupling, etc.

More specifically, the mask M and the mask clamping portion 100 can be coupled such that the mask clamping portion 100 is moved in a direction perpendicular to a surface of the mask M, which is transferred into the process chamber 10, to be coupled with the mask M.

According to a more specific embodiment, the mask clamping portion 100 can include a fitting portion 110, which is fitted into and coupled with a protruding portion 310, and a coupling maintaining portion 120 which maintains a coupling state between the protruding portion 310 and the fitting portion 110 while the fitting portion 110 is fitted into and coupled with the protruding portion 310. Here, the protruding portion 310 protrudes from a bottom surface of the mask M.

The protruding portion 310, which protrudes from the bottom surface of the mask M, is a component for establishing a fitting coupling with the fitting portion 110, and it can adopt various configurations depending on the coupling type.

Also, instead of the protruding portion 310, a concave groove can be formed such that the fitting portion 110 is inserted into the concave groove from the bottom surface of the mask M.

The fitting portion 110 is a component which is fitted and coupled with the protruding portion 310, which protrudes from the bottom surface of the mask M, and can include a concave groove 111 to which the protruding portion 310 is inserted.

Here, as can be seen in FIGS. 3A-3B, the fitting portion 110 is moved in a direction perpendicular to the surface of the mask M, which has been transferred into the process chamber 10, and it is fitted and coupled with the protruding portion 310.

The coupling maintaining portion 120 is a component for maintaining a coupling state between the protruding portion 310 and the fitting portion 110, which are fitted and coupled with each other, and it can adopt various configurations.

According to an embodiment, the fitting portion 110 is provided with the insertion portion 111 into which the protruding portion 310 is inserted, and the coupling maintaining portion 120 can include ball members 121, which are inserted into at least two groove portions 311, and pressurizing members 122 which pressurize the ball members 121 against the groove portions 311. The groove portions 311 are formed on an outer circumferential surface of the protruding portion 310 along the outer circumferential surface.

The pressurizing member 122 is installed to be moved along a longitudinal direction (X-axis direction) within a housing, which constitutes the fitting portion 110, and can pressurizes the ball members 121 against the groove portions 311 while moving.

According to an embodiment, the pressurizing member 122 is provided with an inclined surface 123, which comes into contact with the ball members 121, such that it can pressurize the ball members 121 against the groove portions 311 while moving along the longitudinal direction (X-axis direction) of the protruding portion 310.

And, the pressurizing member 122 is moved in the longitudinal direction (X-axis direction) within the housing, which constitutes the fitting portion 110, by a hydraulic device, etc. which is not shown.

In addition, when the pressurizing member 122 pressurizes the ball member 121 against the groove portions 311, the pressurizing member 122 needs to be fixed in the housing, which constitutes the fitting portion 110, in order to maintain the pressurized state.

In order to accomplish this, the pressurizing member 122 can be fixed by a fixing member 125 which is installed in the housing which constitutes the fitting portion 110.

The fixing member 125 is a component which is installed in the housing, which constitutes the fitting portion 110, and fixes the pressurizing member 122, and it is formed of a hollow ring-shaped tube and expanded by a hydraulic pressure or a pneumatic pressure to directly or indirectly pressurize the pressurizing member 122 and fix the pressurizing member 122 by the fixing member 125 installed in the housing.

By adopting the described configuration, when the coupling maintaining portion 120 maintains the coupling state between the protruding portion 310 and the fitting portion 110 by way of the ball member 121 and the groove portion 311, a position of the protruding portion 310 can be calibrated accurately. Therefore, the alignment between the mask M and the substrate S by the alignment portion 400 can be performed quickly and accurately.

The substrate clamping portion 200 is characterized in being installed in the process chamber 10 to clamp the substrate carrier 320, where the substrate S is absorbed and fixed by the electromagnetic chuck, and can have various configuration depending on the clamping type of the substrate S.

According to an embodiment, the substrate clamping portion 200 can be configured to clamp the substrate carrier 320 by way of a magnetic force coupling, a screw coupling, or a fitting coupling, etc.

More specifically, the substrate carrier 320 and the substrate clamping portion 200 can be coupled such that the substrate clamping portion 200 is moved in a direction perpendicular to a surface of the substrate carrier 320, which is transferred into the process chamber 10, to be coupled with the substrate carrier 320.

According to a more specific embodiment, the substrate clamping portion 200 can include a fitting portion 210, which is fitted into and coupled with a protruding portion 321, and a coupling maintaining portion 220 which maintains a coupling state between the protruding portion 321 and the fitting portion 210 while the fitting portion 210 is fitted into and coupled with the protruding portion 321. Here, the protruding portion 321 protrudes from the bottom surface of the substrate carrier 320.

The protruding portion 321, which protrudes from the bottom surface of the substrate carrier 320, is a component for establishing a fitting coupling with the fitting portion 210, and it can adopt various configurations depending on the coupling type.

Also, instead of the protruding portion 321, a concave groove can be formed such that the fitting portion 210 is inserted into the concave groove from the bottom surface of the substrate carrier 320.

The fitting portion 210 is a component which is fitted and coupled with the protruding portion 321, which protrudes from the bottom surface of the substrate carrier 320, and can include a concave groove 211 to which the protruding portion 321 is inserted.

Here, as can be seen in FIGS. 4A-4B, the fitting portion 210 is moved in a direction perpendicular to the surface of the substrate carrier 320, which has been transferred into the process chamber 10, and it is fitted and coupled with the protruding portion 321.

The coupling maintaining portion 220 is a component for maintaining a coupling state between the protruding portion 321 and the fitting portion 210, which are fitted and coupled with each other, and it can adopt various configurations.

According to an embodiment, the fitting portion 210 is provided with the insertion portion 211 into which the protruding portion 321 is inserted, and the coupling maintaining portion 220 can include ball members 221, which are inserted into at least two groove portions 322, and pressurizing members 222 which pressurize the ball members 221 against the groove portions 322. The groove portions 322 are formed on an outer circumferential surface of the protruding portion 321 along the outer circumferential surface.

The pressurizing member 222 is installed to be moved along a longitudinal direction (X-axis direction) within a housing, which constitutes the fitting portion 210, and can pressurizes the ball members 221 against the groove portions 322 while moving.

According to an embodiment, the pressurizing member 222 is provided with an inclined surface 223, which comes into contact with the ball members 221, such that it can pressurize the ball members 221 against the groove portions 322 while moving along the longitudinal direction (X-axis direction) of the protruding portion 321.

And, the pressurizing member 222 is moved in the longitudinal direction (X-axis direction) within the housing, which constitutes the fitting portion 210, by a hydraulic device, etc. which is not shown.

In addition, when the pressurizing member 222 pressurizes the ball member 221 against the groove portions 322, the pressurizing member 222 needs to be fixed in the housing, which constitutes the fitting portion 210, in order to maintain the pressurized state.

In order to accomplish this, the pressurizing member 222 can be fixed by a fixing member 225 which is installed in the housing which constitutes the fitting portion 210.

The fixing member 225 is a component which is installed in the housing, which constitutes the fitting portion 210, and fixes the pressurizing member 222, and it is formed of a hollow ring-shaped tube and expanded by a hydraulic pressure or a pneumatic pressure to directly or indirectly pressurize the pressurizing member 222 and fix the pressurizing member 222 by the fixing member 225 installed in the housing.

By adopting the described configuration, when the coupling maintaining portion 220 maintains the coupling state between the protruding portion 321 and the fitting portion 210 by way of the ball member 221 and the groove portion 322, a position of the protruding portion 321 can be calibrated accurately. Therefore, the alignment between the mask M and the substrate S by the alignment portion 400 can be performed quickly and accurately.

The alignment portion 400 is a component which moves the substrate carrier 320 relatively with respect to the mask M to align the substrate S, which is clamped by the substrate clamping portion 200, with the mask M, which is clamped by the mask clamping portion 100, and it can adopt various embodiments depending on the alignment method.

According to an embodiment, as can be seen from FIG. 5, the alignment portion 400 can include a first linear moving portion 410, a second linear moving portion 420, and a third linear moving portion 430 which linearly move one of the mask M and the substrate S in a direction parallel with the substrate S.

The first linear moving portion 410, the second linear moving portion 420, and the third linear moving portion 430 are components which are arranged to be perpendicular to one another and linearly move one of the mask M and the substrate S in a direction parallel with the substrate S, and they can adopt various embodiments depending on a linear driving method such as a screw jack method, a belt method, a piezoelectric method, etc.

Here, the first linear moving portion 410, the second linear moving portion 420, and the third linear moving portion 430 can correspond to shapes of a rectangular substrate S and they can drive linear movements in directions parallel with the sides of a rectangle.

By the way, in consideration of that the mask M and the substrate S are fixed and aligned with each other in vertical positions, when a mechanical linear driving method such as a screw jack is applied, a backlash can occur, which can cause an alignment error.

Therefore, in order to prevent the alignment error due to the backlash, linear moving directions of the first linear moving portion 410, the second linear moving portion 420, and the third linear moving portion 430 can be perpendicular to one another as can be seen in FIG. 5, and the linear moving directions can be arranged to be inclined with respect to the vertical direction.

Similarly, when the first linear moving portion 410, the second linear moving portion 420, and the third linear moving portion 430 are inclined with respect to the vertical direction, a weight is applied to all of the first linear moving portion 410, the second linear moving portion 420, and the third linear moving portion 430 in the vertical direction, which can prevent the alignment error due to a backlash.

The adhesion driving portion is a component which adheres the substrate S and the mask M, which are aligned with each other by the alignment portion 400, to each other, and it can include a linear driving unit which is installed on at least one of the substrate clamping portion 200 and the mask clamping portion 100 to cause the mask M and the substrate S to adhere to each other.

As described in the above, when the substrate S and the mask M are not aligned with each other accurately, an error is generated while forming a pattern on the substrate S, and it can degenerate a yield. Therefore, it is very important to align the substrate S and the mask M with each other before the substrate processing process is performed.

Meanwhile, the substrate S is transferred alone or fixed on the substrate carrier 320 to be transferred for performing the substrate processing process, and the substrate S is normally fixed on the substrate carrier 320 to be transferred.

By the way, when the substrate S, which is fixed on the substrate carrier 320, is not accurately attached, it can delay a subsequent alignment process between the substrate S and the mask M or can cause a failure in the substrate processing process.

More specifically, since, after the substrate S is fixed on the substrate carrier 320, the substrate carrier 320 can be flipped, that is, turned upside down or forced into a vertical position depending on the processes performed, the coupling state and alignment state between the substrate carrier 320 and the substrate S play a very important role for subsequent processes.

Therefore, it is preferable to perform the alignment between the substrate carrier 320 and the substrate S when the substrate S is received on the substrate carrier 320.

FIG. 6 is a plan view showing an alignment process between the substrate S and the substrate carrier 320.

In particular, when the substrate S is positioned to be apart from the substrate carrier 320 by a vertical spacing before the substrate S is received on the substrate carrier 320, the alignment between the substrate S and the substrate carrier 320 is performed by using a first mark M1, which is marked on the substrate S, and a second mark M2, which is marked on the substrate carrier 320.

Here, the alignment process between the substrate S and the substrate carrier 320 is almost the same as or quite similar to the aforementioned alignment process between the mask M and the substrate S, and, therefore, a detailed explanation is omitted.

And, when the alignment between the substrate S and the substrate carrier 320 is included, the substrate processing method to which the present invention is applied can comprise a first aligning step for aligning horizontal positions of the substrate S and the substrate carrier 320, a substrate receiving step for receiving the substrate S on the substrate carrier 320 to be fixed thereon, a second aligning step for aligning the horizontal positions of the substrate S, which is received on the substrate carrier 320, and the mask M, a mask adhering step for adhering the mask M to the substrate S, and a depositing step for performing a thin film deposition process while the mask M and the substrate S are adhered to each other.

### INDUSTRIAL APPLICABILITY

The present invention can be applied to a vapor deposition device and, more specifically, to an aligner structure and an alignment method.

1. An aligner structure of a substrate processing apparatus for processing a substrate after the substrate and a mask are transferred vertically to a process chamber, respectively, and the substrate and the mask are transferred and adhered to each other, the aligner structure comprising:
a mask clamping portion which is installed in the process chamber to clamp the mask;
a substrate clamping portion which clamps a substrate carrier on which the substrate is absorbed and fixed by an electrostatic chuck;
an alignment portion which relatively moves the substrate carrier with respect to the mask such that the substrate, which is clamped by the substrate clamping portion, and the mask, which is clamped by the mask clamping portion are aligned with each other; and
an adhesion driving portion which causes the substrate and the mask, which are aligned by the alignment portion, to adhere to each other.

2. The aligner structure according to claim 1, wherein the mask clamping portion is characterized in clamping the mask by way of a magnetic force coupling, a screw coupling, or a fitting coupling.

3. The aligner structure according to claim 1, wherein the substrate clamping portion is characterized in clamping the substrate carrier by way of a magnetic force coupling, a screw coupling, or a fitting coupling.

4. The aligner structure according to claim 1, wherein the mask clamping portion includes a fitting portion, which is fitted into and coupled with a protruding portion, and a coupling maintaining portion which maintains a coupling state between the protruding portion and the fitting portion while the fitting portion is fitted into and coupled with the protruding portion, wherein the protruding portion protrudes from a bottom surface of the mask.

5. The aligner structure according to claim 1, wherein the substrate clamping portion includes a fitting portion, which is fitted into and coupled with a protruding portion, and a coupling maintaining portion which maintains a coupling state between the protruding portion and the fitting portion while the fitting portion is fitted into and coupled with the protruding portion, wherein the protruding portion protrudes from a bottom surface of the substrate carrier.

6. The aligner structure according to claim 4, wherein the fitting portion is provided with the insertion portion into which the protruding portion is inserted, and the coupling maintaining portion includes ball members, which are inserted into at least two groove portions, and pressurizing members which pressurize the ball members against the groove portions, wherein the groove portions are formed on an outer circumferential surface of the protruding portion along the outer circumferential surface.

7. The aligner structure according to claim 6, wherein the pressurizing members are provided with inclined surfaces, which come into contact with the ball members and move along a longitudinal direction of the protruding portion to pressurize the ball members against the groove portions.

8. The aligner structure according to claim 1, wherein the adhesion driving portion includes a linear driving unit which is installed on at least one of the substrate clamping portion and the mask clamping portion to cause the mask M and the substrate S to adhere to each other.

9. The aligner structure according to claim 1, wherein the alignment portion includes a first linear moving portion, a second linear moving portion, and a third linear moving portion which linearly move one of the mask and the substrate in a direction parallel with the substrate.

10. The aligner structure according to claim 9, wherein linear moving directions of the first linear moving portion, the second linear moving portion, and the third linear moving portion are perpendicular to one another and inclined with respect to a vertical direction.

11. The aligner structure according to claim 1, wherein the substrate processing apparatus performs a deposition process by using an evaporation source which evaporates a deposition material, wherein the deposition material contains at least one of an organic material, an inorganic material, and a metal material.

12. The aligner structure according to claim 5, wherein the fitting portion is provided with the insertion portion into which the protruding portion is inserted, and the coupling maintaining portion includes ball members, which are inserted into at least two groove portions, and pressurizing members which pressurize the ball members against the groove portions, wherein the groove portions are formed on an outer circumferential surface of the protruding portion along the outer circumferential surface.

13. The aligner structure according to claim 2, wherein the alignment portion includes a first linear moving portion, a second linear moving portion, and a third linear moving portion which linearly move one of the mask and the substrate in a direction parallel with the substrate.

14. The aligner structure according to claim 3, wherein the alignment portion includes a first linear moving portion, a second linear moving portion, and a third linear moving portion which linearly move one of the mask and the substrate in a direction parallel with the substrate.

15. The aligner structure according to claim 4, wherein the alignment portion includes a first linear moving portion, a second linear moving portion, and a third linear moving portion which linearly move one of the mask and the substrate in a direction parallel with the substrate.

16. The aligner structure according to claim 5, wherein the alignment portion includes a first linear moving portion, a second linear moving portion, and a third linear moving portion which linearly move one of the mask and the substrate in a direction parallel with the substrate.
